(19) United States
(12) Patent Application Publication
(10) Pub. No.: US 2013/0070430 A1
(43) Pub. Date: Mar. 21, 2013

(54) DISPLAY DEVICE

(71) Applicants: Hideyuki Hirota, Tokyo (JP); Kazuhiro Tsuzuki, Tokyo (JP); Masumi Ihara, Tokyo (JP); Norimitsu Hasegawa, Hyogo (JP)

(72) Inventors: Hideyuki Hirota, Tokyo (JP); Kazuhiro Tsuzuki, Tokyo (JP); Masumi Ihara, Tokyo (JP); Norimitsu Hasegawa, Hyogo (JP)

(73) Assignee: MITSUBISHI ELECTRIC CORPORATION, Tokyo (JP)

(21) Appl. No.: 13/701,802

(22) PCT Filed: Sep. 17, 2010
(86) PCT No.: PCT/JP2010/005683

§ 371 Date: Dec. 3, 2012

(51) Int. Cl. H05K 7/06

(52) U.S. Cl. 361/748

(57) ABSTRACT

A display device includes: circuit board 6 provided inside a display panel; flat cable 10 attached to connector 11 provided on the board 6; outlet section 10A which is provided in a position on the rotational axis side of the display panel at substantially the same height as that of the board 6, of which the corner of the open edge part is formed by a radius of curvature of a predetermined value or more, and which draws the cable 10 attached to the connector 11 to the outside of the panel; and a draw path section of flat part 4b and contact part 13, of which the corner coming into contact with the cable 10 attached to the connector 11 is formed by a radius of curvature of a predetermined value or more, and which leads the cable 10 to the section 10A without bending.

### TECHNICAL FIELD

The present invention relates to a structure of drawing a flat cable attached to a connector that is mounted on a circuit board inside a display housing to the outside of the display housing.

### BACKGROUND ART

As a conventional display device, there is the one including: a frame in which a cut-out portion is formed; a connector with a slider part mounted on a circuit board inside the frame; and a flat cable of which the one end is connected to the connector via the slider part, and of which the other end passes through the cut-out portion of the frame and is bent to the side opposite to a display surface outside the frame (for example, see Patent Document 1).

In the display device, even when the flat cable attached to the connector is bent along the frame, the flat cable is supported by the frame portion that is the outer edge part of the cut-out portion of the frame, and an opening-direction force to be applied to the slider part of the connector is suppressed. In this way, the disconnection of the flat cable from the connector can be prevented.

### PRIOR ART DOCUMENTS

### Patent Documents

Patent Document 1: JP-A-2000-39621

### SUMMARY OF THE INVENTION

When a conventional structure as represented by Patent Document 1 is applied to an openable display device, the stress caused by the bending of the flat cable due to openings and closings of the display panel is concentrated on the portion of the flat cable that comes into contact with the cut-out portion of the frame. Consequently, when the openings and closings of the display panel are repeated, there is a possibility that the flat cable is disconnected at the portion in contact with the cut-out portion of the frame.

The present invention is made to resolve the foregoing problem, and an object of the invention is to provide a display device capable of reducing the load on the flat cable with the openings and closings of the display panel to thereby prevent disconnection thereof.

A display device of the present invention is a display device in which a display panel opens and closes by rotating around a rotational axis, the device including: a circuit board provided inside the display panel; a flat cable attached to a connector provided on the circuit board; an outlet section which is provided in a position on a rotational axis side of the display panel at substantially the same height as that of the circuit board, of which the corner of the open edge part is formed by a radius of curvature of a predetermined value or more, and which draws the flat cable attached to the connector to the outside of the display panel; and a draw path section of which the corner coming into contact with the flat cable attached to the connector is formed by a radius of curvature of a predetermined value or more, and which leads the flat cable to the outlet section without bending the flat cable.

According to the invention, there is an advantageous effect that reduces the load on the flat cable with the openings and closings of the display panel to thereby prevent disconnection thereof.

### BRIEF DESCRIPTION OF THE DRAWINGS

FIG. 1 is an exploded perspective view of a display panel portion of a display device to which the present invention is applied.

FIG. 2 is a perspective view showing a state after the assembly of the display panel portion in FIG. 1.

FIG. 3 is a perspective view showing a configuration on a front panel side in a conventional display panel.

FIG. 4 is a sectional view in a closed state of the conventional display panel.

FIG. 5 is a sectional view in an open state of the conventional display panel.

FIG. 6 is a perspective view showing a configuration on a front panel side of a display device according to Embodiment 1 of the present invention.

FIG. 7 is a perspective view showing a rear panel of the display device according to Embodiment 1.

FIG. 8 is a sectional view in a closed state of the display panel of Embodiment 1.

FIG. 9 is a sectional view in an open state of the display panel of Embodiment 1.

FIG. 10 is a perspective view showing a state before the assembly of a reinforcing plate.

FIG. 11 is a perspective view showing a state after the assembly of the reinforcing plate.

### BEST MODE FOR CARRYING OUT THE INVENTION

In the following, in order to explain the present invention in more detail, embodiments of the invention will be described with reference to the accompanying drawings.

### Embodiment 1

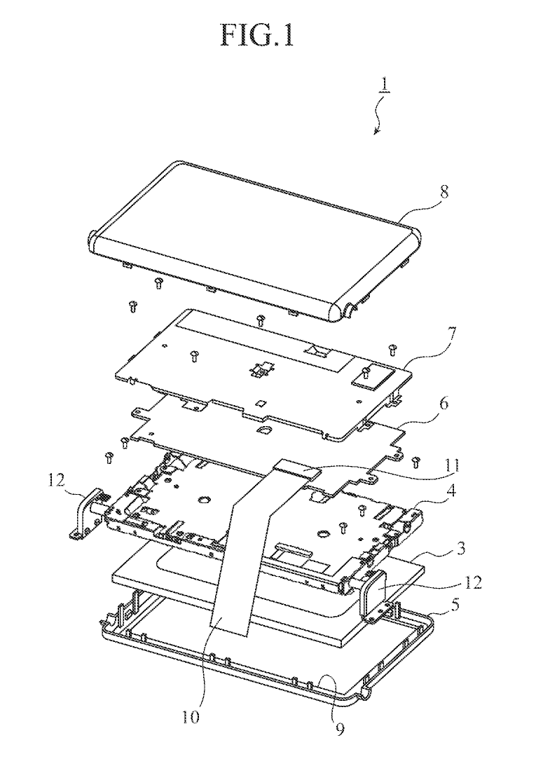

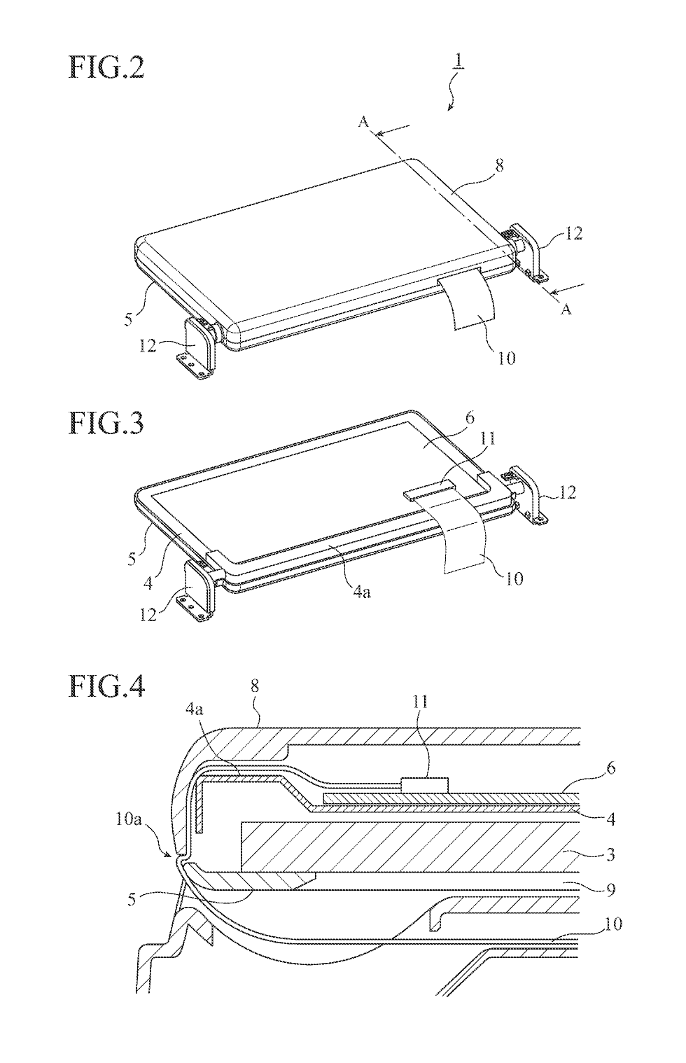

FIG. 1 is an exploded perspective view of a display panel portion of a display device to which the present invention is applied, and FIG. 2 is a perspective view showing a state after the assembly of the display panel portion of FIG. 1. In FIG. 1, a liquid crystal 3 and a holder 4 are fixed to a front panel 5 with a screw, and a circuit board 6 and a shield plate 7 are mounted on the holder 4. A connector 11 is mounted on the circuit board 6, and a flat cable 10 is attached to the connector 11.

When a rear panel 8 is assembled to the front panel 5 on which the liquid crystal 3, the holder 4, the circuit board 6 and the shield substrate 7 are installed, the display panel 1 shown in FIG. 2 is built. It is noted that a display screen is provided when the liquid crystal 3 is exposed through an opening 9 of the front panel 5. Moreover, a rotational axis part 12 is provided on either side of the display panel 1 as shown in FIG. 2, and the display panel 1 is opened and closed by rotating around the rotation axis of the rotational axis parts 12.

FIG. 3 is a perspective view showing a configuration on a front panel side in a conventional display panel. As shown in FIG. 3, in the conventional display panel, it is configured that an edge part 4a on the outlet side of a flat cable 10 in a holder 4 is elevated toward the rear panel 8 side relative to a plane including the circuit board 6, in order to install the rotation axis of the rotational axis parts 12. Therefore, in order to draw the flat cable 10 attached to the connector 11 on the circuit board 6 to the outside of the display panel, the cable needs to climb over the edge part 4a of the holder 4.

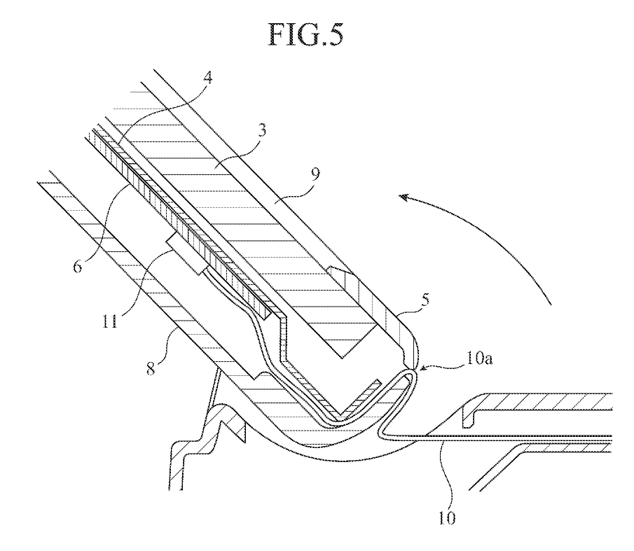

FIG. 4 is a sectional view in a closed state of the conventional display panel, and shows the cross section on the outlet side of the flat cable 10 in the display panel taken along a line A-A of FIG. 2. In the conventional display device, as shown in FIG. 4, the edge part 4a of the holder 4 is elevated toward the rear panel 8 side, and an outlet section 10a is formed on the front panel 5 side. The flat cable 10 climbs over the edge part 4a of the holder 4, is bent in the direction of the outlet section 10a, passes through the narrow space between the holder 4 and the inner wall of the rear panel 8, and then is drawn from the outlet section 10a.

As mentioned above, since the space for passing the flat cable 10 to be drawn to the outside needs to be ensured between the edge part 4a of the holder 4 and the inner wall of the rear panel 8, the thickness of the rear panel 8 cannot be made thicker. For this reason, the end part of the opening of the outlet section 10a is inevitably a corner part having a small radius of curvature R in accordance with the thickness of the rear panel 8. Accordingly, the flat cable 10 coming into contact with the end part of the outlet section 10a is drawn with steeply bent at a large curvature.

FIG. 5 is a sectional view in an open state of the conventional display panel, and shows, as with FIG. 4, a cross section of the outlet side of the flat cable 10 in the display panel taken along the line A-A of FIG. 2. When the display panel is opened in an arrow direction of FIG. 5 from the closed state shown in FIG. 4, the stress due to the bending is applied to the flat cable 10.

In other words, after climbing over the edge part 4a, the flat cable 10 once bends in the direction of the outlet section 10a, and is further drawn out from the outlet section 10a located on the front panel 5 side from the bent position. At this time, when the display panel is put in an open state, the flat cable 10 at the outlet section 10a, as shown in FIG. 5, is bent greatly such that the bending direction of the cable turns to a direction contrary to the case in the closed state of FIG. 4. For this reason, when the openings and closings of the display panel are repeated, there is a possibility that the flat cable 10 may be disconnected due to the stress caused by the bending of the flat cable 10 at the outlet section 10a.

Accordingly, in the present invention, the outlet section for drawing the flat cable 10 attached to the connector 11 to the outside of the display panel is formed at substantially the same height as that of the circuit board 6 in a position on the rotational axis side of the display panel, and also a draw path section for leading the flat cable 10 attached to the connector 11 to the outlet section without bending the cable is prepared. Further, it is configured that the corner of the open edge part of the outlet section and the corner of the draw path section are formed by a radius of curvature R of a predetermined value or more, such that the flat cable 10 coming into contact with these corners is bent gently at a small curvature. According to such a configuration, the stress load on the flat cable 10 with the openings and closings of the display panel is reduced to thereby prevent disconnection thereof. Hereinafter, a specific configuration will be described.

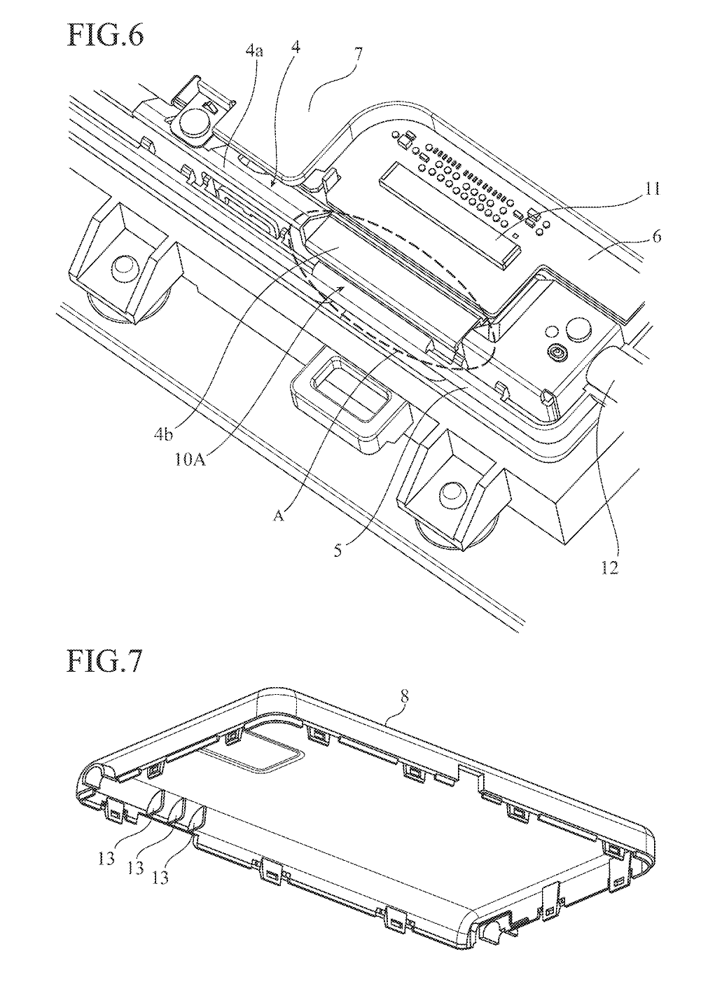

FIG. 6 is a perspective view showing a configuration on a front panel side of a display device according to Embodiment 1 of the present invention, and the same reference numerals are given to the components that are identical or equivalent to those of FIG. 1 to FIG. 5. As shown in FIG. 6, in the invention, an outlet section 10A is formed at substantially the same height as that of a circuit board 6. Moreover, at an edge part 4a on the outlet section 10A side of a holder 4, a path through which the flat cable 10 to be drawn to the outside passes is prepared as a flat part 4b having the same height as that of the circuit board 6.

For example, the edge part 4a on the outlet section 10A side of the holder 4 is, as shown in FIG. 6, a plate material that is bent to be convex toward the rear panel 8 side; thus, the portion of the edge part 4a to be passed by the flat cable 10 attached to the connector 11 is notched, and the flat part 4b is formed with lowered by one step so as to have substantially the same height as that of the circuit board 6, as shown in a portion A surrounded by a broken line in FIG. 6.

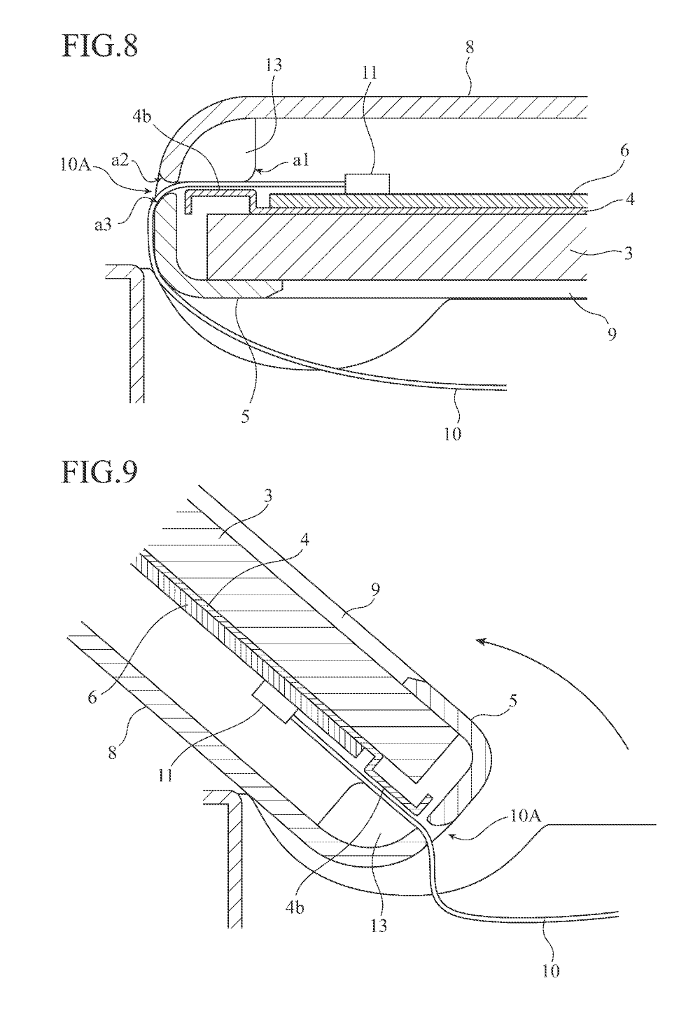

FIG. 7 is a perspective view showing a rear panel of the display device according to Embodiment 1. The rear panel 8 is provided with contact parts 13 to come into contact with the flat cable 10 as shown in FIG. 7. When the contact parts 13 come into contact with the flat cable 10 on the opposite side of the flat part 4b, as described below with reference to FIG. 8, the flat cable 10 is led to the outlet section 10A without bending. In other words, the flat part 4b and the contact part 13 serve as the draw path section for leading the flat cable 10 naturally straight to the outlet section 10A without bending.

It is noted that the following case is illustrated in FIG. 6: the portion of the holder 4 to be passed by the flat cable 10 is notched, and is folded to have substantially the same height as that of the circuit board 6 to thus form the flat part 4b, the configuration is not limited thereto. For example, the portion of the holder 4 to be passed by the flat cable 10 may be cut out and then separately attached thereto with a member serving as the flat part. Also in this instance, an edge of a metal plate or the like having a small radius of curvature R is not provided for the portions that come into contact with the flat cable 10.

FIG. 8 is a sectional view in a closed state of the display panel of Embodiment 1, and shows, as with FIG. 4, a cross section on the outlet side of the flat cable 10 in the display panel taken along the line A-A of FIG. 2. In the display device of Embodiment 1, as described above, the portion in the holder 4 to be passed by the flat cable 10 is adapted as the flat part 4b having substantially the same height as that of the circuit board 6.

In addition, the outlet section 10A also has substantially the same height as that of the circuit board 6 as shown in FIG. 8. By means of the contact part 13 of the rear panel 8 and the flat part 4b of the holder 4, the flat cable 10 is drawn to the outside from the outlet section 10A without bending.

Further, a corner part a1 of the contact part 13, a corner part a2 of the open edge part of the outlet section 10A, and a corner part a3 of the open edge part of the outlet section 10A each are formed by a radius of curvature R of a predetermined value or more, such that the flat cable 10 is bent gently at a curvature that is less than a predetermined value.

FIG. 9 is a sectional view in an open state of the display panel of Embodiment 1, and shows, as with FIG. 8, a cross section on the outlet side of the flat cable 10 in the display panel taken along the line A-A of FIG. 2. When the display panel is opened in an arrow direction of FIG. 9 from the closed state shown in FIG. 8, the flat cable 10 is bent gently at the corner of the open edge part of the outlet section 10A as shown in FIG. 9. Accordingly, even if the openings and closings of the display panel are repeated, the stress caused by the bending of the flat cable 10 is substantially alleviated, which enables to prevent the disconnection of the flat cable 10.

As described above, according to Embodiment 1, the display device includes: the circuit board 6 provided inside the display panel; the flat cable 10 attached to the connector 11 provided on the circuit board 6; the outlet section 10A which is provided in a position on the rotational axis side of the display panel at substantially the same height as that of the circuit board 6, of which the corner of the open edge part is formed by a radius of curvature of a predetermined value or more, and which draws the flat cable 10 attached to the connector 11 to the outside of the display panel; and the draw path section, composed of the flat part 4b and the contact part 13, of which the corner coming into contact with the flat cable 10 attached to the connector 11 is formed by a radius of curvature of a predetermined value or more, and which leads the flat cable 10 to the outlet section 10A without bending the flat cable 10. With such a configuration, the stress load on the flat cable 10 with the openings and closings of the display panel can be reduced, and the disconnection of the flat cable 10 due to the accumulation of the load can be prevented.

It is noted that though in the above Embodiment 1 the draw path section composed of the flat part 4b and the contact part 13 are illustrated, the present invention is not limited to the above configuration. For example, the flat part may be provided on the rear panel 8 side, and the contact part may be provided for the holder 4; it may also be configured that the flat part or the contact part is provided for both of the holder 4 and the rear panel 8. In other words, any configuration that leads the flat cable 10 attached to the connector 11 to the outlet section 10A without bending may be adopted.

Moreover, in the above Embodiment 1, the following mechanism for restricting the movement of the flat cable 10 may be provided in order to alleviate the load to be applied to the connector 11 due to the insertion and removal of the flat cable 10.

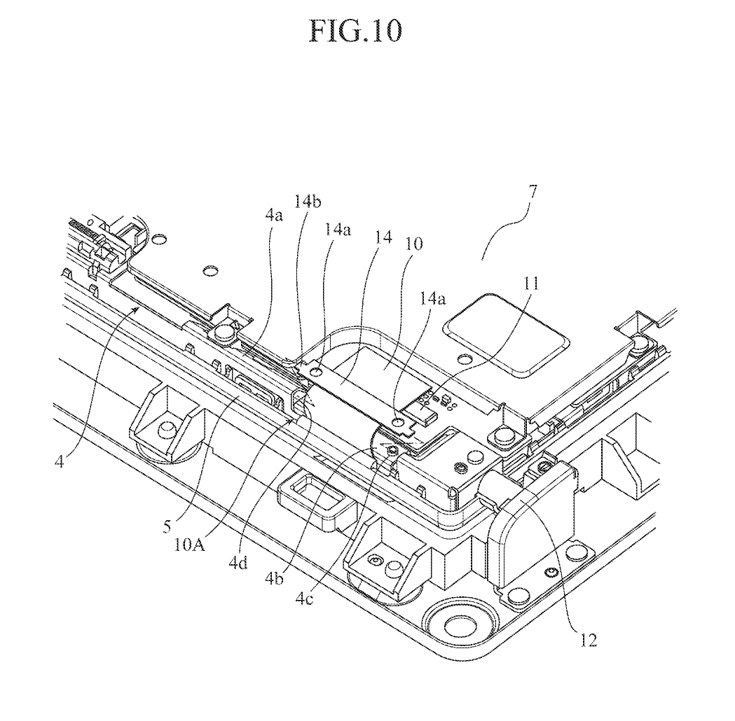

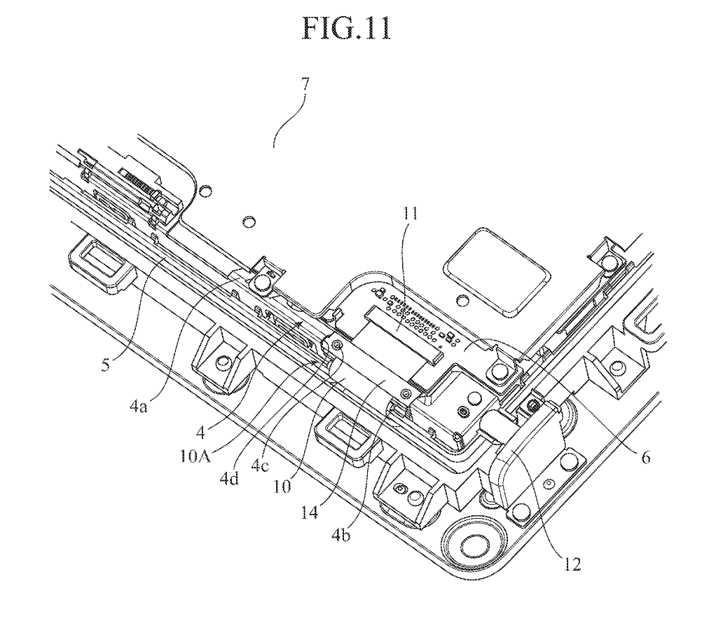

FIG. 10 is a perspective view showing a state before the assembly of a reinforcing plate, and FIG. 11 is a perspective view showing a state after the mounting of the reinforcing plate in FIG. 10. In FIG. 10 and FIG. 11, the same reference numerals are given to the components that are identical or equivalent to those of FIG. 1 to FIG. 9.

Upon the insertion and removal of the flat cable 10 into/from an external connector (not shown) of the display panel, there is a possibility such that the flat cable 10 may be disconnected from the connector 11 when a load is applied to the connector 11 due to the movement of the flat cable 10 in a width direction or a vertical direction thereof.

Accordingly, as shown in FIG. 10 and FIG. 11, a reinforcing plate 14 and pins 4c for restricting the movement of the flat cable 10 are provided. In an example shown in FIG. 10, the pins 4c are formed on the flat part 4b at an interval that is substantially the same as the width of the flat cable 10. When the flat cable 10 attached to the connector 11 is passed between the pins 4c, the movement of the flat cable 10 in the width direction is restricted. In addition, the reinforcing plate 14 is provided with an engagement hole 14a through which the pin 4c is to be inserted, and a mount engagement parts 14b are formed at the respective ends thereof.

As mentioned above, since the flat part 4b is formed such that the portion of the holder 4 to be passed by the flat cable 10 is notched, and is lowered by one step so as to have substantially the same as that of the circuit board 6, notch parts 4d as shown in FIG. 10 are formed on both sides the flat part 4b.

The reinforcing plate 14 is mounted such that the mount engagement part 14b of the reinforcing plate 14 is inserted into the notch part 4d, and that the pin 4c is inserted into the engagement hole 14a.

With the foregoing configuration, the movement of the flat cable 10 in the width direction and vertical direction is restricted, and it is thereby possible to considerably alleviate the load applied to the connector 11 due to the insertion and removal of the flat cable 10. In this way, it is possible to prevent the flat cable 10 from be disconnected from the connector 11 due to the load due to the insertion and removal of the flat cable 10.

The effects similar to the above can be obtained even in the case where the flat cable 10 is screwed from the top through the reinforcing plate, instead of the pin 4c and the mount engagement part 14b.

Note that according to the present invention, the configurations illustrated in the above embodiments may be modified or omitted as needed within the scope of the invention.

### INDUSTRIAL APPLICABILITY

Since the display device of the present invention can reduce the stress load on the flat cable with the openings and closings of the display panel to thereby prevent disconnection thereof, it can be suitable for, for instance, a vehicle-mounted display device which is frequently opened and closed.

1. A display device in which a display panel opens and closes by rotating around a rotational axis, the device comprising:
a circuit board provided inside the display panel;
a flat cable attached to a connector provided on the circuit board;
an outlet section which is provided in a position on a rotational axis side of the display panel at substantially the same height as that of the circuit board, of which the corner of the open edge part is formed by a radius of curvature of a predetermined value or more, and which draws the flat cable attached to the connector to the outside of the display panel; and
a draw path section of which the corner coming into contact with the flat cable attached to the connector is formed by a radius of curvature of a predetermined value or more, and which leads the flat cable to the outlet section without bending.

2. The display device according to claim 1, wherein the draw path section is composed of:
a flat part at substantially the same height as that of the circuit board through which the flat cable attached to the connector passes before leading to the outlet section; and
a contact part which is placed opposite to the flat part, of which the corner coming into contact with the flat cable is formed by a radius of curvature of a predetermined value or more, and which comes into contact with the flat cable from the opposing side of the flat part to lead the flat cable to the outlet section without bending the cable.

3. The display device according to claim 1, further comprising:
a movement restricting mechanism for restricting movement of the flat cable attached to the connector.
